(19) United States
(12) Patent Application Publication
(10) Pub. No.: US 2012/0315726 A1
(43) Pub. Date: Dec. 13, 2012

(54) METHOD OF MANUFACTURING A SEMICONDUCTOR CHIP PACKAGE

(76) Inventors: HAK-KYOON BYUN, Hwaseong-si (KR); Bu-Won Kim, Gwangju-si (KR); Raehyung Do, Dongnae-gu (KR); JongBo Shim, Asan-si (KR); Woodong Lee, Cheonan-si (KR)

(21) Appl. No.: 13/491,055

(22) Filed: Jun. 7, 2012

(30) Foreign Application Priority Data
Jun. 7, 2011 (KR) 10-2011-0054444

(51) Int. Cl. H01L 21/82

(52) U.S. Cl. 438/109; 257/E21.602

(57) ABSTRACT

Provided are methods of manufacturing a semiconductor chip package. The method includes forming a plurality of semiconductor chips, each of which includes a semiconductor substrate having a front and back surfaces facing each other, a chip pad provided on the front surface of the semiconductor substrate, and an interconnection pattern extending from the chip pad along a sidewall of the semiconductor substrate, stacking the semiconductor chips such that the interconnection patterns of the semiconductor chips directly contact each other, and reflowing the interconnection patterns of the semiconductor chips to connect the stacked semiconductor chips with each other.

### CROSS-REFERENCE TO RELATED APPLICATIONS

This U.S. non-provisional patent application claims priority under 35 U.S.C. §119 to Korean Patent Application No. 10-2011-0054444, filed on Jun. 7, 2011, in the Korean Intellectual Property Office, the entire contents of which are herein incorporated by reference.

### TECHNICAL FIELD

Embodiments of the inventive concept relate generally to a method of manufacturing a semiconductor chip package. More particularly, embodiments of the inventive concept relate to a method of manufacturing a semiconductor chip package including a plurality of sequentially stacked semiconductor chips.

### DISCUSSION OF RELATED ART

Various packaging technologies have been employed to package small-sized semiconductor products. For instance, chip-scale packaging may allow for a further reduced size of semiconductor devices. For smaller and more reliable semiconductor devices, there is a need of efficiently connecting semiconductor chips to one another in a package.

### SUMMARY

Embodiments of the inventive concept provide packaging methods that can easily form electric connections between stacked semiconductor chips.

According to an exemplary embodiment of the inventive concept, a method of manufacturing a semiconductor chip package includes forming a plurality of semiconductor chips, each of which comprises a semiconductor substrate having a front surface and a back surface facing each other, a chip pad provided on the front surface of the semiconductor substrate, and an interconnection pattern extending from the chip pad to cover a sidewall of the semiconductor substrate, stacking the semiconductor chips such that the interconnection patterns of the semiconductor chips directly contact each other, and reflowing the interconnection patterns of the semiconductor chips to connect the stacked semiconductor chips with each other.

### BRIEF DESCRIPTION OF THE DRAWINGS

Exemplary embodiments will be more clearly understood from the following brief description taken in conjunction with the accompanying drawings. The accompanying drawings represent non-limiting, exemplary embodiments as described herein, wherein:

FIG. 1 is a flowchart illustrating a method of manufacturing a semiconductor chip package according to an exemplary embodiment of the inventive concept;

FIG. 2 is a plan view a semiconductor substrate provided with semiconductor chips according to an exemplary embodiment of the inventive concept;

FIG. 3 is an enlarged plan view of a portion A of FIG. 2;

FIGS. 4A through 4G are sectional views provided to describe a method of manufacturing a semiconductor chip package according to an embodiment of the inventive concept and taken along line I-I′ of FIG. 3;

FIGS. 5A through 5C are sectional views provided to describe a method of manufacturing a semiconductor chip package according to an embodiment of the inventive concept and taken along line I-I′ of FIG. 3;

FIGS. 6 and 7 are diagrams of a semiconductor chip included in a semiconductor chip package according to an exemplary embodiment of the inventive concept;

FIG. 8 is a diagram of a semiconductor chip package according to an embodiment of the inventive concept;

FIG. 9 is a diagram of a semiconductor chip package according to an embodiment of the inventive concept;

FIG. 10 is a diagram of a semiconductor chip package according to an embodiment of the inventive concept;

FIG. 11 is a diagram of a semiconductor chip package according to an embodiment of the inventive concept:

FIG. 12 is a schematic diagram of a package module including a semiconductor chip package according to an exemplary embodiment of the inventive concept; and

FIG. 13 is a schematic diagram of an electronic system including a semiconductor chip package according to an exemplary embodiment of the inventive concept.

### DETAILED DESCRIPTION

Exemplary embodiments of the inventive concept will now be described more fully with reference to the accompanying drawings. The exemplary embodiments of the inventive concept may, however, be embodied in many different forms and should not be construed as being limited to the embodiments set forth herein. In the drawings, the thicknesses of layers and regions may be exaggerated for clarity. Like reference numerals in the drawings may denote like or similar elements throughout the specification and the drawings.

It will be understood that when an element is referred to as being “connected” or “coupled” to another element, it can be directly connected or coupled to the other element or intervening elements may be present. As used herein, the singular forms “a,” “an” and “the” are intended to include the plural forms as well, unless the context clearly indicates otherwise.

According to an exemplary embodiment of the inventive concept, a semiconductor chip package includes a plurality of sequentially stacked semiconductor chips. In an embodiment, the plurality of the semiconductor chips are stacked on a package substrate (for instance, a printed circuit board (PCB)). Each of the semiconductor chips includes chip pads that are connected to the package substrate by bonding wires. However, in the case of using the bonding wires, each of the semiconductor chips may have an additional space (e.g., a bonding pad forming region), allowing the bonding wires to be connected to each other. As a consequence, an interconnection structure for connecting the semiconductor chips may be complicated. According to an exemplary embodiment of the inventive concept, a semiconductor chip package includes a plurality of sequentially stacked semiconductor chips, each of which has interconnection patterns for an electric connection with other semiconductor chips. As a result, the semiconductor chip package can have a simplified interconnection structure.

Hereinafter, a method of manufacturing a semiconductor chip package according to an exemplary embodiment of the inventive concept will be described with reference to the accompanying drawings.

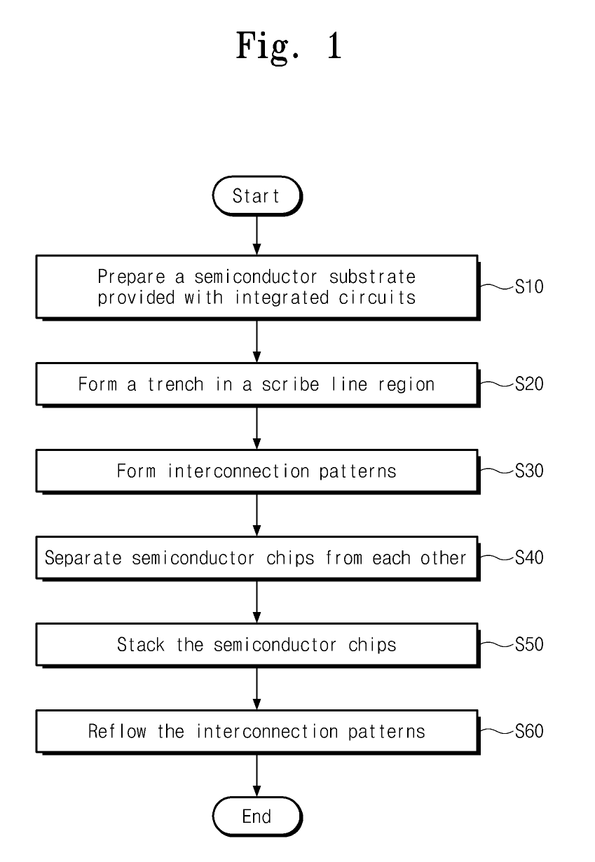

FIG. 1 is a flowchart illustrating a method of manufacturing a semiconductor chip package according to an exemplary embodiment of the inventive concept.

Referring to FIG. 1, a semiconductor substrate is prepared (S10). The semiconductor substrate includes chip regions, each of which includes semiconductor integrated circuits and chip pads connected to the semiconductor integrated circuits, and a scribe line region disposed between the chip regions. A trench is formed in the scribe line region of the semiconductor substrate (S20). Interconnection patterns are formed to extend from an inner wall of the trench to a top surface of the chip pads (S30). The chip regions of the semiconductor substrate are separated from each other to form semiconductor chips (S40). The semiconductor chips are vertically stacked such that the interconnection patterns formed on the semiconductor chips directly contact each other (S50). A reflow process is performed to reflow the interconnection patterns of the semiconductor chips, so that the stacked semiconductor chips are connected with each other (S60).

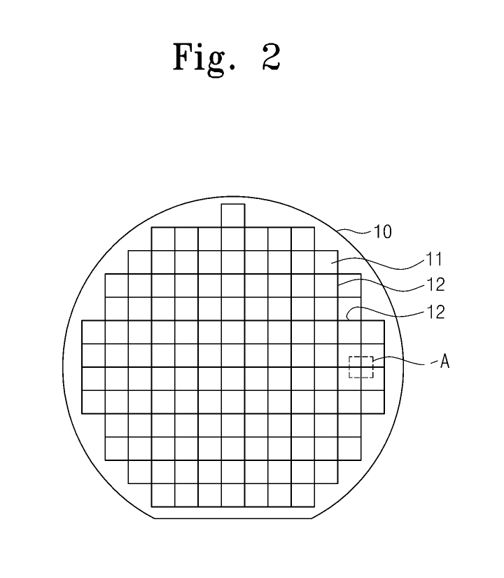

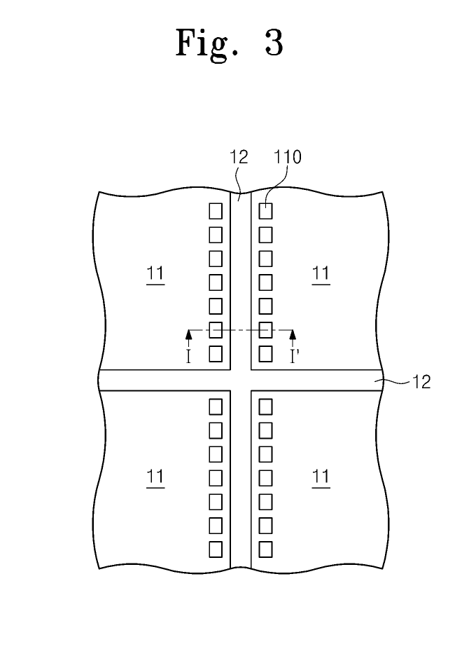

FIG. 2 is a plan view a semiconductor substrate 10 including semiconductor chips 100 according to an exemplary embodiment of the inventive concept, and FIG. 3 is an enlarged plan view of a portion A of FIG. 2.

Referring to FIGS. 2 and 3, a semiconductor substrate 10 (e.g., a wafer) includes chip regions 11, which will be used as semiconductor chips, respectively, and a scribe line region 12 disposed between the chip regions 11. The chip regions 11 are two-dimensionally arranged on a front surface of the semiconductor substrate 10, and the chip regions 11 are separated from each other by the scribe line region 12 surrounding the respective chip regions 11.

According to an embodiment, the semiconductor substrate 10 is a silicon substrate. Semiconductor integrated circuits (not shown) are integrated on the chip regions 11 of the semiconductor substrate 10 by semiconductor fabricating processes. The semiconductor integrated circuits are protected by an insulating material and are electrically connected to external electronic devices via the chip pads 110. In an embodiment, the chip pads 110 are disposed adjacent to the scribe line region 12. However, with regard to positions of the chip pads 110, the embodiments of the inventive concept are not limited thereto.

In an embodiment, the semiconductor integrated circuits integrated on the chip regions 11 include semiconductor memory devices, such as dynamic random access memories (DRAMs), static RAMs (SRAMs), or FLASH memories. Alternatively, the semiconductor integrated circuits include micro electro mechanical system (MEMS) devices, optoelectronic devices, or processors (e.g., CPUs or DSPs).

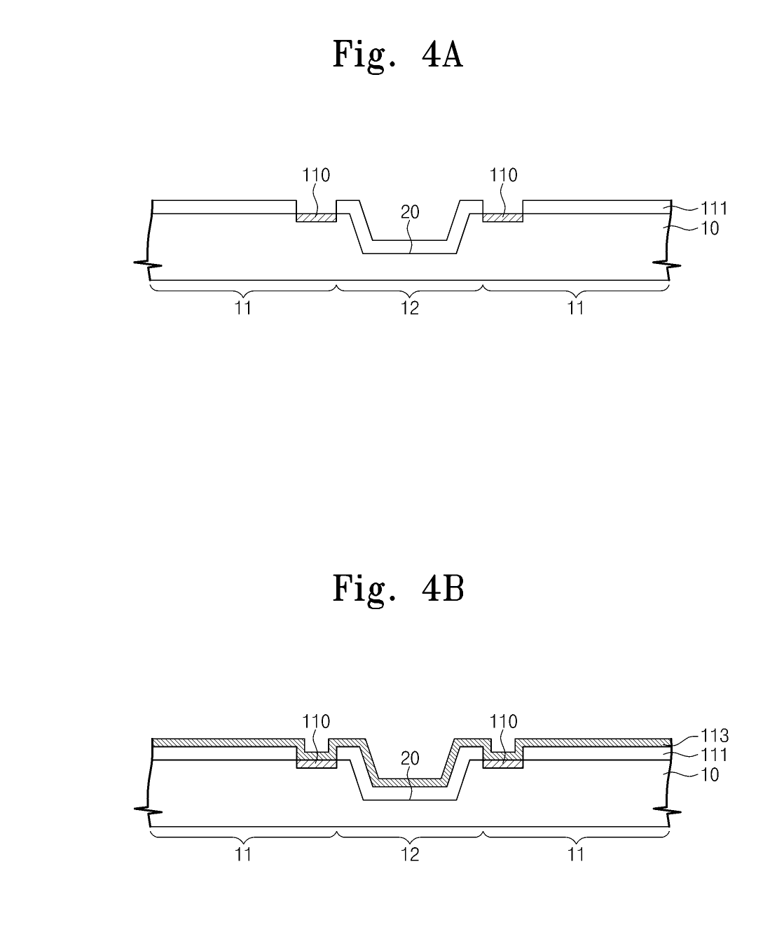

FIGS. 4A through 4G are sectional views provided to describe a method of manufacturing a semiconductor chip package according to an embodiment of the inventive concept. For example, FIGS. 4A through 4G are sectional views taken along line of FIG. 3.

Referring to FIG. 4A, a trench 20 is formed in the scribe line region 12 of the semiconductor substrate 10. In more detail, the semiconductor substrate 10 includes a front surface exposing the chip pads 110 and a back surface facing the front surface. The formation of the trench 20 includes forming a first mask pattern (not shown) on the front surface of the semiconductor substrate 10 to expose the scribe line region 12 and then anisotropically etching the semiconductor substrate 10 using the first mask pattern as an etch mask. As a result, the trench 20 is formed between the chip regions 11 and adjacent to the chip pads 110. In an embodiment, the trench 20 is formed to have a sloped sidewall. The trench 20 is formed to have a depth greater than a thickness of the semiconductor integrated circuit integrated on the chip regions 11. After the formation of the trench 20, the first mask pattern is removed to expose the chip pads 110 of the chip regions 11.

Thereafter, a passivation layer 111 is formed on the front surface of the semiconductor substrate 10 provided with the trench 20. Due to the presence of the passivation layer 111, the semiconductor integrated circuits integrated on the chip regions 11 can be protected from the external environment. The passivation layer 111 includes openings locally exposing the chip pads 110. The passivation layer 111 is formed of silicon oxide, silicon nitride, or any combination thereof.

Referring to FIG. 4B, a metallic underlying layer 113 (e.g., an under bump metallurgy (UBM)) is conformally formed on the passivation layer 111 including the openings. In an embodiment, the metallic underlying layer 113 includes an adhesion layer having a good adhesion property with the passivation layer 111, a diffusion barrier layer of preventing a metallic material from being diffused in the chip pads 110, and a wettable layer having a good wetting property to an interconnection pattern 120. For instance, the adhesion layer is formed of aluminum (Al), chromium (Cr), or titanium (Ti), and the diffusion barrier layer is formed of nickel (Ni), and the wettable layer is formed of silver (Ag), gold (Au), copper (Cu), nickel (Ni), palladium (Pd) or platinum (Pt). The metallic underlying layer 113 is formed by a sputtering method.

Referring to FIG. 4C, a second mask pattern 115 is formed on the metallic underlying layer 113. The second mask pattern 115 is used to form an interconnection pattern 120. The second mask pattern 115 is formed by coating a photoresist film on a metallic underlying layer 113 and then performing a development process on the photoresist film.

In an embodiment, the second mask pattern 115 is formed to have openings partially exposing the metallic underlying layer 113 on the chip pads 110. According to an embodiment, the openings extend to expose the metallic underlying layer 113 on the trench 20. As shown in FIG. 4C, a portion of the second mask pattern 115 remains on the trench 20. Alternatively, the second mask pattern 115 is formed to expose the metallic underlying layer 113 on the chip pads 110, which are disposed adjacent to each other, without the remaining portion. In other words, the second mask pattern 115 is formed such that a top surface of the metallic underlying layer 113 is exposed on the adjacent chip pads 110 and on the trench 20.

Referring to FIG. 4D, interconnection patterns 120 are formed in the openings of the second mask pattern 115. The interconnection patterns 120 are locally formed on the chip pads 110, respectively. In an embodiment, the interconnection patterns 120 extend to cover the metallic underlying layer 113 on sidewalls of the trench 20. The interconnection patterns 120 are formed of a solder material or a metallic material. In an embodiment, the interconnection patterns 120 are formed by coating a solder paste using a screen printing method or a dotting method. Alternatively, the interconnection patterns 120 are formed of at least one of metals having relatively high conductivity, such as copper (Cu), a iron-nickel alloy, aluminum (Al), or a stainless steel, or alloys thereof.

In an embodiment, in the case that the portion of the second mask pattern 115 remains on a bottom surface of the trench 20, a pair of the interconnection patterns 120 disposed on the adjacent chip regions 11 are formed to have a mirror symmetry. Alternatively, when there is no remaining portion of the second mask pattern 115, the interconnection patterns 120 disposed at both sides of the trench 20 are connected with each other on the bottom surface of the trench 20.

Referring to FIG. 4E, the second mask pattern 115 is removed, and the metallic underlying layer 113 is patterned to form metal patterns 114. The formation of the metal pattern 114 may include anisotropically etching the metallic underlying layer 113 using the interconnection patterns 120 as an etch-mask. As a result of the formation of the metal pattern 114, the passivation layer 111 is exposed on the chip region and the trench 20.

Referring to FIG. 4F, an adhesion pattern 130 is formed on the chip regions 11 to cover the passivation layer 111. The adhesion pattern 130 is formed to expose the interconnection patterns 120. In an embodiment, the adhesion pattern 130 is formed to have the same or substantially the same thickness as the interconnection pattern 120. The adhesion pattern 130 includes an insulating adhesive material, such as an epoxy resin or a silicone resin.

Referring to FIG. 4G, the chip regions 11 of the semiconductor substrate 10 are separated from each other.

In an embodiment, the separation of the chip regions 11 includes a process of grinding the back surface of the semiconductor substrate 10 to expose a bottom surface of the interconnection pattern 120. For instance, the grinding process is performed until the semiconductor substrate 10 has a thickness of about 30 μm to about 100 μm. In an embodiment, during the grinding process, the chip regions 11 of the semiconductor substrate 10 are separated into a plurality of the semiconductor chips 100. According to an embodiment, each of the semiconductor chips 100 includes the interconnection patterns 120 connected to the chip pads 110. In an embodiment, before performing the grinding process, a dummy substrate (not shown) is attached on the front surface of the semiconductor substrate 10 to support the semiconductor chips 10 that are to be separated from each other. The dummy substrate is removed after the grinding process.

In an embodiment, the separation of the chip regions 11 is performed so that the semiconductor substrate 10 is cut between a pair of adjacent interconnection patterns 120. For instance, a sawing process is performed along the scribe line region 12 of the semiconductor substrate 10 to separate the chip regions 11 from each other. In an embodiment, the sawing process is performed using a sawing wheel or a laser.

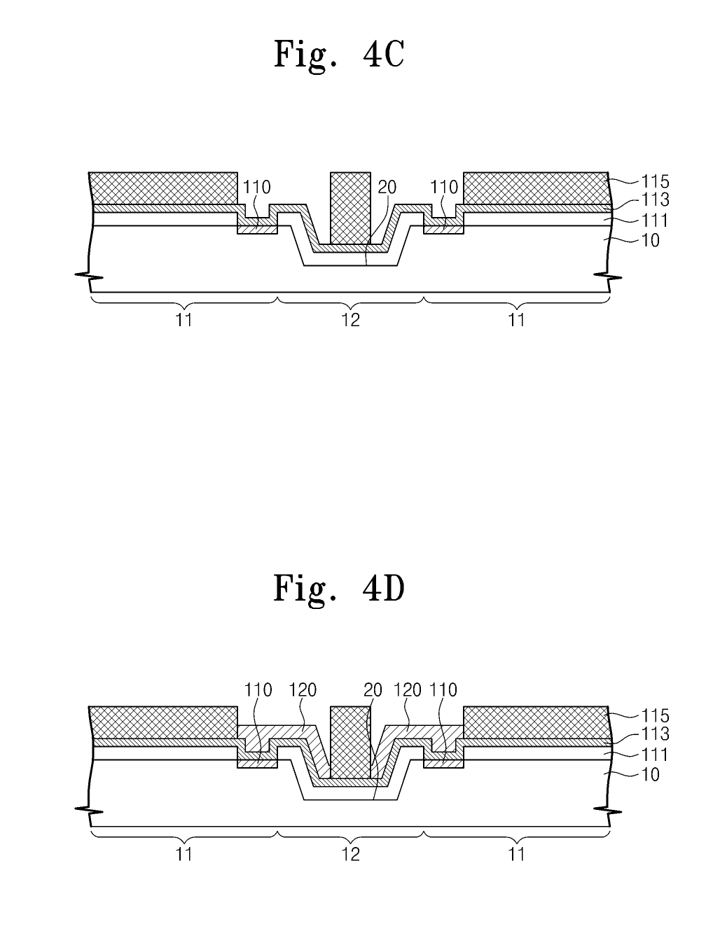

FIGS. 5A through 5C are sectional views provided to describe a method of manufacturing a semiconductor chip package according to an embodiment of the inventive concept. For example, FIGS. 5A through 5C are sectional views taken along line I-I′ of FIG. 3.

Referring to FIGS. 4E and 5A, after the formation of the interconnection patterns 120 on the chip pads 110 and the trench 20, the back surface of the semiconductor substrate 10 is polished so that the chip regions 11 of the semiconductor substrate 10 are separated from each other. In an embodiment, before performing the polishing process, a dummy substrate (not shown) is attached on the front surface of the semiconductor substrate 10 to support the semiconductor chips 10 that are to be separated from each other. The dummy substrate is removed after the polishing process.

Referring to FIG. 5B, an adhesion layer 135 is formed on the back surfaces of the separated semiconductor chips 100. The adhesion layer 135 includes an insulating adhesive material, such as an epoxy resin or a silicone resin. In an embodiment, the adhesion layer 135 includes an adhesion tape attached on the back surfaces of the semiconductor chips 100.

Thereafter, a cutting process is performed to cut the adhesion layer 135 between the semiconductor chips 100. As a result, as shown in FIG. 5C, each of the separated semiconductor chips 100 is formed to include an adhesion pattern 137 on the back surface of the semiconductor substrate 10. The process of cutting the adhesion layer is performed by sawing or a laser.

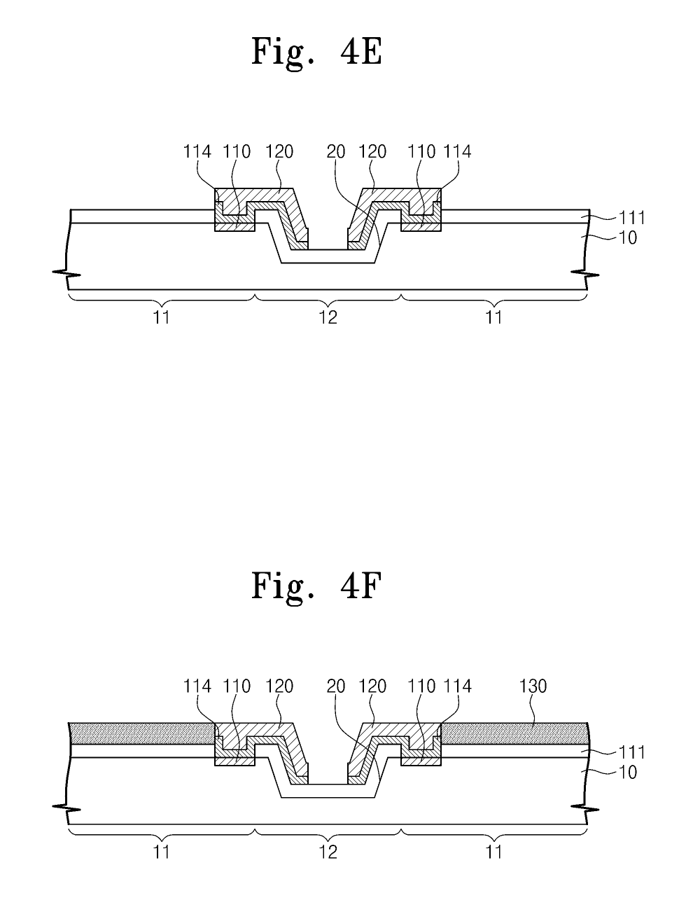

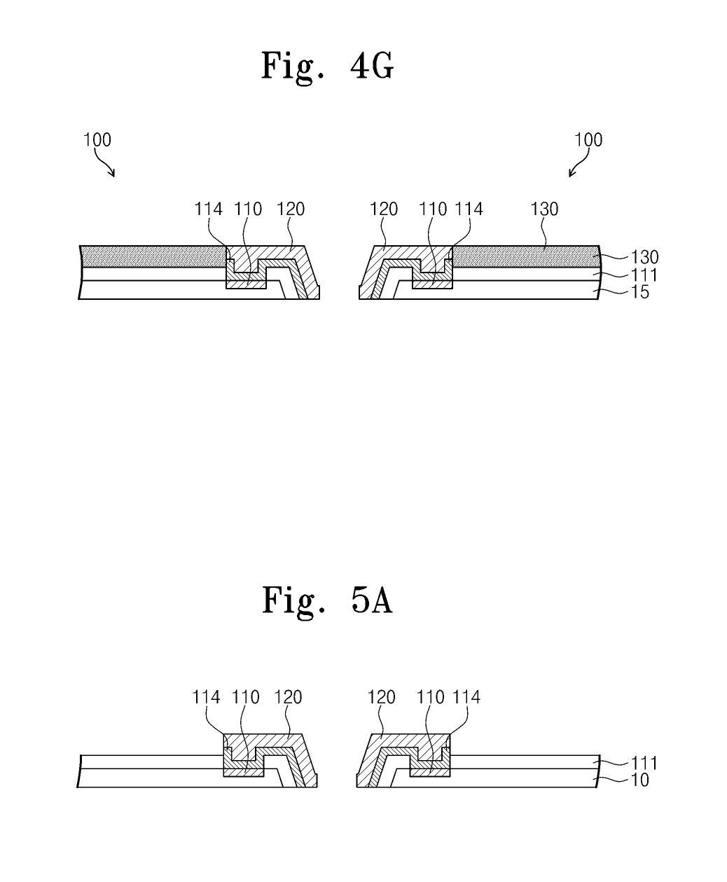

FIGS. 6 and 7 show a semiconductor chip manufactured by a method according to an exemplary embodiment of the inventive concept.

Referring to FIGS. 6 and 7, a semiconductor chip 100 includes a semiconductor substrate 10 integrated with semiconductor integrated circuits, chip pads 110 connected to the semiconductor integrated circuits, and interconnection patterns 120.

The semiconductor substrate 10 includes a front surface 10a and a back surface 10b facing each other. The chip pads 110 are formed on the front surface 10a of the semiconductor substrate 10. The chip pads 110 are arranged at edge regions of the semiconductor substrate 10. The interconnection patterns 120 are formed of a conductive material and are connected to the chip pads 110, respectively. The interconnection patterns 120 are formed of a solder material or a metallic material. Each of the interconnection patterns 120 extends from a top surface of the chip pad 110 to a side surface of the semiconductor substrate 10. An adhesion pattern 130 is attached to the front surface 10a of the semiconductor chip 100. In an embodiment, the adhesion pattern 130 is attached to the back surface 10b of the semiconductor chip 100, as shown in FIG. 5C.

As shown in FIG. 6, each of the interconnection patterns 120 includes a sidewall portion 123 covering a side surface of the semiconductor chip 100, a first connection portion 121 extending from the sidewall portion 123 to the front surface 10a of the semiconductor chip 100, and a second connection portion 125 extending from the sidewall portion 123 and protruding outward from the semiconductor substrate 10. The interconnection patterns 120 are connected to the chip pads 110 through the first connection portions 121. In an embodiment, each first connection portion 121 has a horizontal width greater than a horizontal width of each corresponding second connection portion. Alternatively, the first and second connection portions 121 and 125 have the same or substantially the same horizontal width as each other. In an embodiment, the first connection portion 121, the sidewall portion 123, and the second connection portion 125 have a substantially uniform thickness.

As shown in FIG. 7, each interconnection pattern 120 includes a sidewall portion 123 covering a side surface of the semiconductor chip 100 and a connection portion 121 extending from the sidewall portion 123 to the front surface 10a of the semiconductor chip 100. The interconnection patterns 120 are connected to the chip pads 110 through the connection portions 121. According to an embodiment, the semiconductor chip 100 has a reduced width compared with a width of the semiconductor chip 100 shown in FIG. 6.

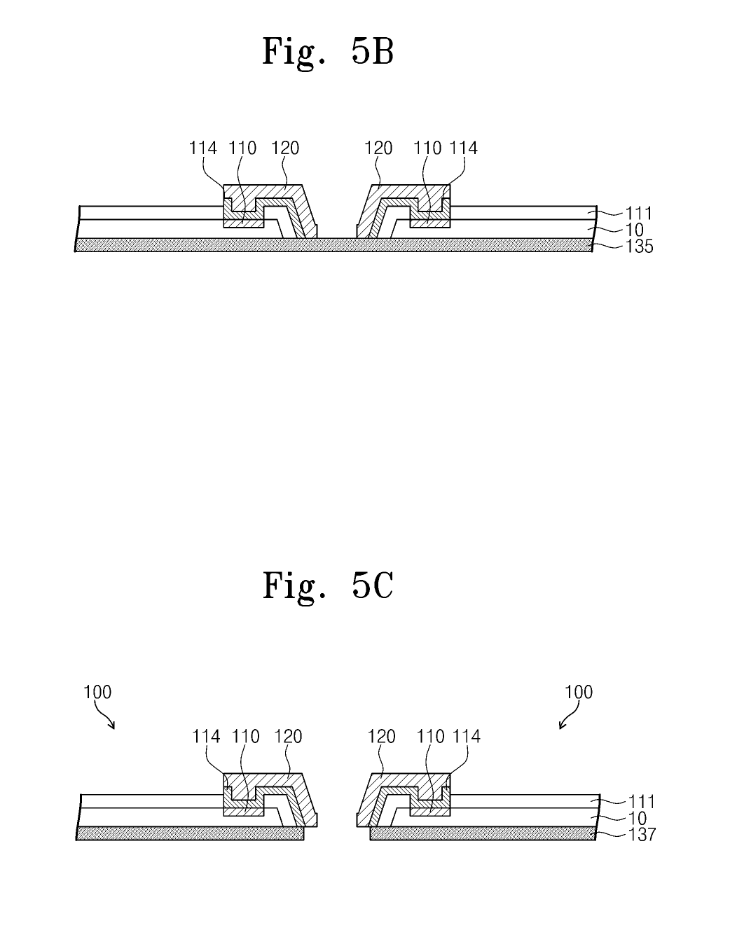

FIG. 8 is a diagram illustrating a semiconductor chip package according to an embodiment of the inventive concept.

Referring to FIG. 8, a semiconductor chip package 310 includes a plurality of semiconductor chips 100 stacked on a package substrate 200.

According to an embodiment, the package substrate 200 includes one of a variety of types of substrates, such as a printed circuit board, a flexible substrate, or a tape substrate. The package substrate 200 with top and bottom surfaces includes bonding pads 210, I/O terminals 230 and a core interconnection layer 220. The bonding pads 210 are arranged at an upper surface of the package substrate 200, and the I/O terminals 230 are arranged at a lower surface of the package substrate 200. The bonding pads 210 are electrically connected to the I/O terminals 230, respectively, via the core interconnection layer 220. The bonding pads 210 are connected to the semiconductor chips 100 via interconnection patterns 120. As a result, electric signals (e.g., data signals and control signals) transmitted from an external device can be delivered to the semiconductor chips 100 via the bonding pads 210 and the interconnection patterns 120. The I/O terminals 230 electrically connect the semiconductor chip package 310 to an external device (not shown). The I/O terminals 230 include solder balls or solder bumps.

The semiconductor chips 100 are sequentially stacked on the package substrate 200. As described with reference to FIGS. 6 and 7, each of the semiconductor chips 100 includes the chip pads 110 connected to the semiconductor integrated circuits and the interconnection patterns 120.

In an embodiment, the semiconductor chips 100 in the semiconductor chip package 310 have the same or substantially the same size. In an embodiment, the semiconductor chips 100 have sizes different from each other. In an embodiment, all of the semiconductor chips 100 include memory chips or non-memory chips. Alternatively, some of the semiconductor chips 100 are memory chips and others of the chips 100 are non-memory chips. According to an embodiment, the semiconductor chip package 310 has memory chips that include the same or different types of memory circuits. According to an embodiment, the memory circuits include a dynamic random access memory (DRAM), a static RAM (SRAM), a programmable read only memory (PROM), an erasable PROM (EPROM), an electrically erasable PROM (EEPROM), a FLASH memory, a phase changeable RAM (PRAM), a resistive RAM (RRAM), a magnetic RAM (MRAM), or a ferroelectric RAM (FRAM). The non-memory chips include a micro electro mechanical system (MEMS) device, an optoelectronic device, or a processor (e.g., CPU, DSP).

In an embodiment, the semiconductor chips 100 have an offset stack structure. For example, a lowermost semiconductor chip of the semiconductor chips 100 is stacked on the package substrate 200 such that the interconnection patterns 120 of the lowermost semiconductor chip are connected to the bonding pads 210 of the package substrate 200, and others of the semiconductor chips 100 are sequentially stacked in an offset manner. For example, the semiconductor chips 100 are stepwise stacked to form a terraced structure. In an embodiment, the semiconductor chips 100 are stacked such that center points of the chips 100 are located on a straight or slightly curved line that is not perpendicular to the top surface of the package substrate 200.

In an embodiment, the semiconductor chips 100 are stacked such that the interconnection patterns 120 of the vertically adjacent semiconductor chips 100 overlap each other. In other words, the semiconductor chips 100 are stacked in such a way that the first connection portion 121 of a first interconnection pattern 120 in a first semiconductor chip 100 contacts the second connection portion 125 of a second interconnection pattern 120 in a second semiconductor chip 100 disposed on the first semiconductor chip 100, wherein the first and second interconnection patterns 120 correspond to each other.

In an embodiment, a thermal process is performed after the stacking of the semiconductor chips 100 on the package substrate 200. The thermal process is performed under a high temperature of about 150° C. to about 250° C. As the result of the thermal process, the interconnection patterns 120 are reflowed to electrically and physically connect the semiconductor chips 100 with each other. After the thermal process, an encapsulating layer (not shown) is formed to cover the stacked semiconductor chips 100.

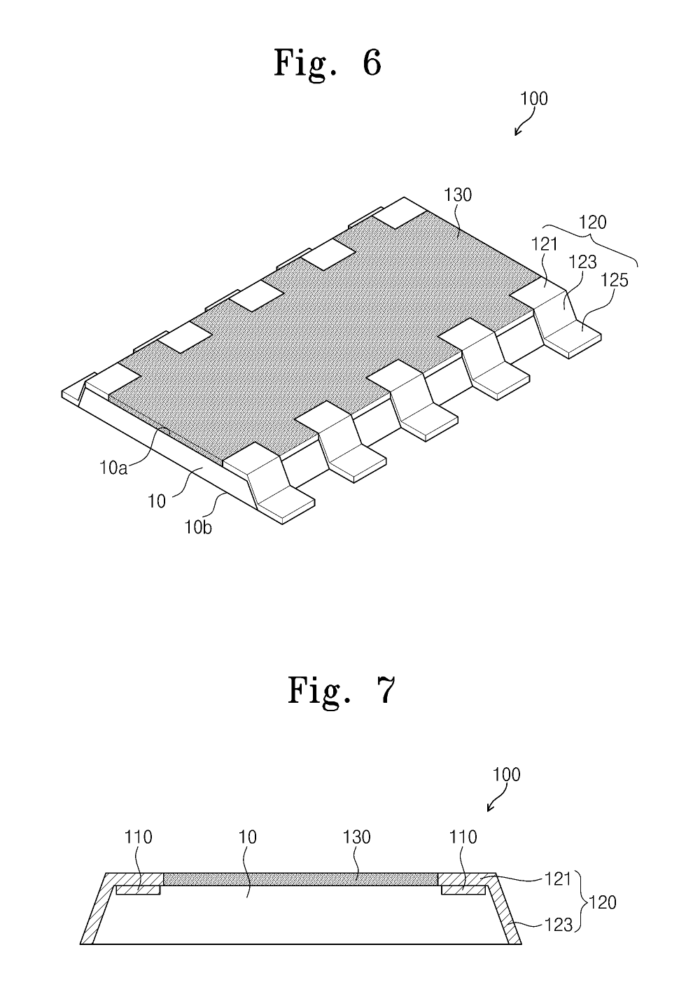

FIG. 9 is a diagram illustrating a semiconductor chip package according to an embodiment of the inventive concept.

Referring to FIG. 9, a semiconductor chip package 320 includes a plurality of semiconductor chips 100 stacked on a package substrate 200. Some of the semiconductor chips 100 (hereinafter, a first group) are stacked on the underlying semiconductor chip or the package substrate 200 along a first direction L1, and others of the semiconductor chips 100 (hereinafter, a second group) are stacked along a second direction L2 different from the first direction L1. In an embodiment, the first direction L1 is slanted, for instance, rightwards, with respect to a normal line to a top surface of the package substrate 200, and the second direction L2 is slanted, for instance, leftwards, with respect to the normal line. In other words, the semiconductor chips 100 of the first group are stacked such that edges of the second group of chips 100 (e.g., edges of the interconnection patterns 120) are aligned along a first vertical line V1, and the semiconductor chips 100 of the second group are stacked such that edges of the second group of chips 100 are aligned along a second vertical line V2. The first and second vertical lines V1 and V2 are perpendicular to the top surface of the package substrate 200 and are spaced apart from each other. In an embodiment, the semiconductor chips 100 of the first and second groups are alternately stacked on the package substrate 200 as shown in FIG. 9.

As described with reference to FIGS. 6 and 7, each of the semiconductor chips 100 includes the semiconductor substrate 10, the chip pads 110, and the interconnection patterns 120. A thermal process is performed after the stacking of the semiconductor chips 100 on the package substrate 200. As a result of the thermal process, the interconnection patterns 120 are reflowed to electrically and physically connect the semiconductor chips 100 with each other.

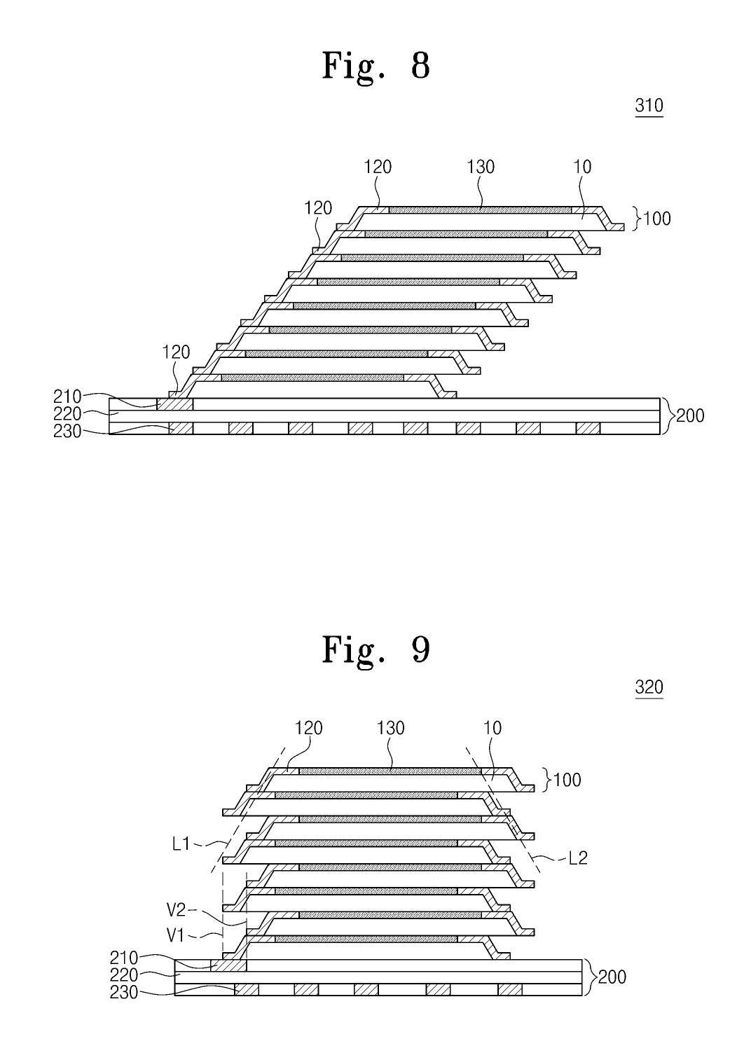

FIG. 10 is a diagram illustrating a semiconductor chip package according to an embodiment of the inventive concept.

Referring to FIG. 10, a semiconductor chip package 330 includes a plurality of semiconductor chips 100 stacked on a package substrate 200. In an embodiment, even-numbered semiconductor chips of the semiconductor chips 100 are stacked in an inverted structure, e.g., upside down, and odd-numbered semiconductor chips of the chips 100 are stacked, with the back surfaces of the odd-numbered semiconductor chips facing downward. Each of the semiconductor chips 100 includes an adhesion pattern 130 and an adhesion layer 140 attached to the front and back surfaces, respectively, of the semiconductor substrate 10 of the chip 100.

In more detail, as described with reference to FIGS. 6 and 7, each of the stacked semiconductor chips 100 includes the semiconductor substrate 10, the chip pads 110 and the interconnection patterns 120. The semiconductor chips 100 are stacked such that the interconnection patterns 120 disposed vertically adjacent to each other are connected with each other in such a way that the first connection portions or the second connection portions of the patterns 120 contact each other.

In an embodiment, a thermal process is performed after the stacking of the semiconductor chips 100 on the package substrate 260. As a result of the thermal process, the interconnection patterns 120 are reflowed to electrically and physically connect the semiconductor chips 100 with each other.

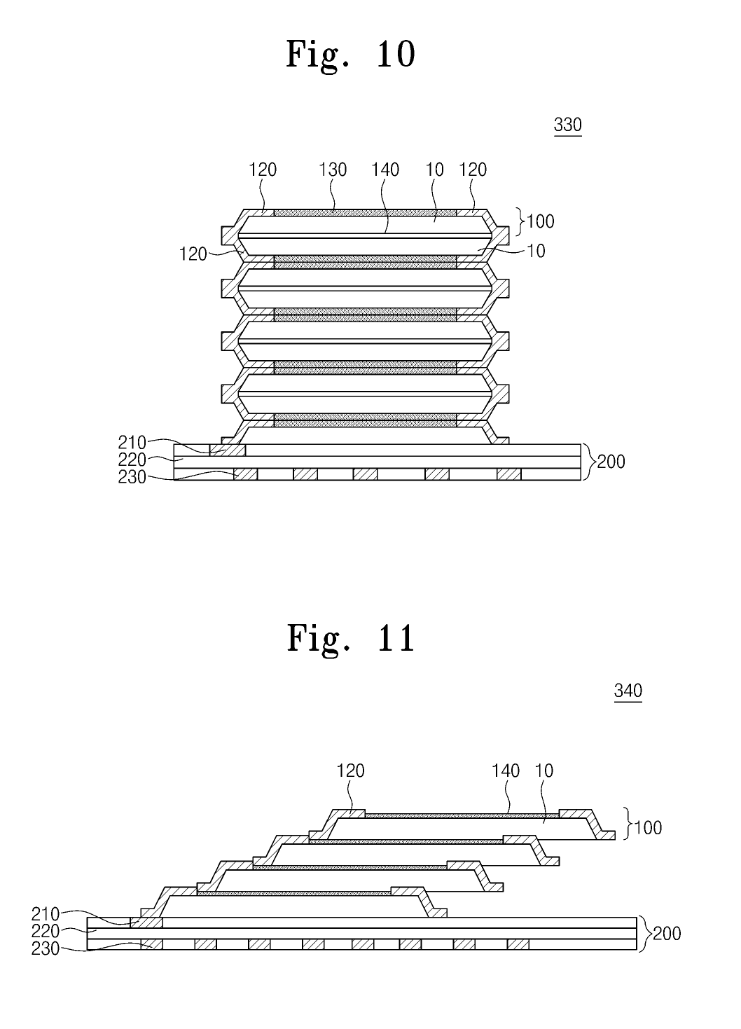

FIG. 11 is a diagram illustrating a semiconductor chip package according to an embodiment of the inventive concept.

Referring to FIG. 11, a semiconductor chip package 340 includes the semiconductor chips 100 stacked to have an offset stack structure similar to the structure described with reference to FIG. 8. For example, edges of the stacked semiconductor chips 100 are aligned along a diagonal line slanted from a line normal to a top surface of the package substrate 200. Each of the stacked semiconductor chips 100 includes a semiconductor substrate 10, chip pads 110 and interconnection patterns 120, and an exposed insulating layer (e.g., the passivation layer 111) on a front surface of the semiconductor substrate 10. In an embodiment, an adhesion tape 140 is attached to the insulating layer of the semiconductor chip 100.

In an embodiment, the semiconductor chips 100 are stacked such that the interconnection patterns 120 disposed vertically adjacent to each other directly contact each other through sidewalls of the patterns 120. For instance, the semiconductor chips 100 are stacked in such a way that a sidewall of the first connection portion (refer to 121 of FIG. 6) of a first interconnection pattern 120 contacts a sidewall of the second connection portion (refer to 125 of FIG. 6) of a second interconnection pattern 120 adjacently disposed on the first interconnection pattern 120.

Thereafter, a thermal process is performed to reflow the interconnection patterns. As a result, the semiconductor chips 100 are electrically and physically connected with each other.

The semiconductor chip packaging methods described above can be applied to diverse types of semiconductor devices and package modules including the semiconductor devices.

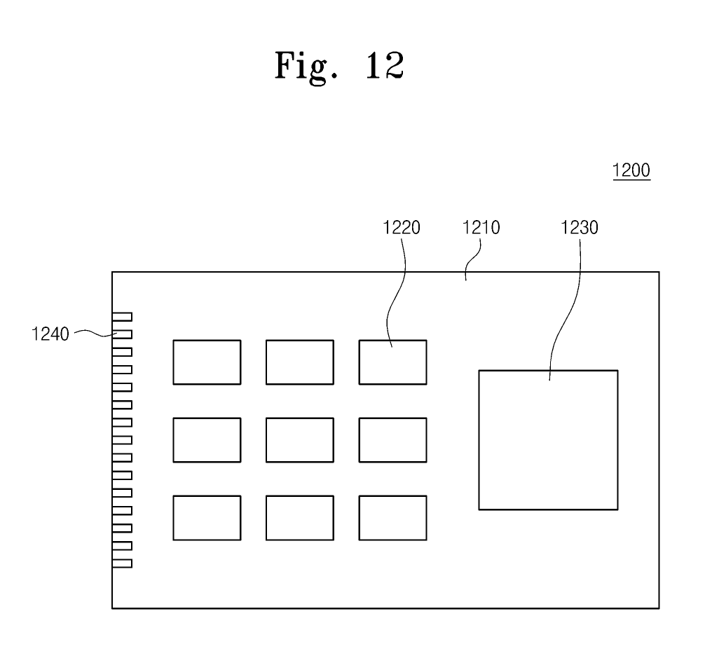

FIG. 12 is a schematic diagram illustrating a package module including a semiconductor chip package according to an exemplary embodiment of the inventive concept.

Referring to FIG. 12, a package module 1200 includes a module substrate 1210 with input/output connecting terminals 1240. The package module 1200 further includes semiconductor chip packages 1220 and 1230 mounted on the module substrate 1210. In an embodiment, the semiconductor chip packages 1220 and 1230 are configured to have the same or substantially the same technical features as one of the semiconductor chip packages described with reference to FIGS. 6 through 11. The input/output connecting terminals 1240 is provided at an edge of the module substrate 1210, and enable the package module 1200 to be electrically connected to an external electronic device.

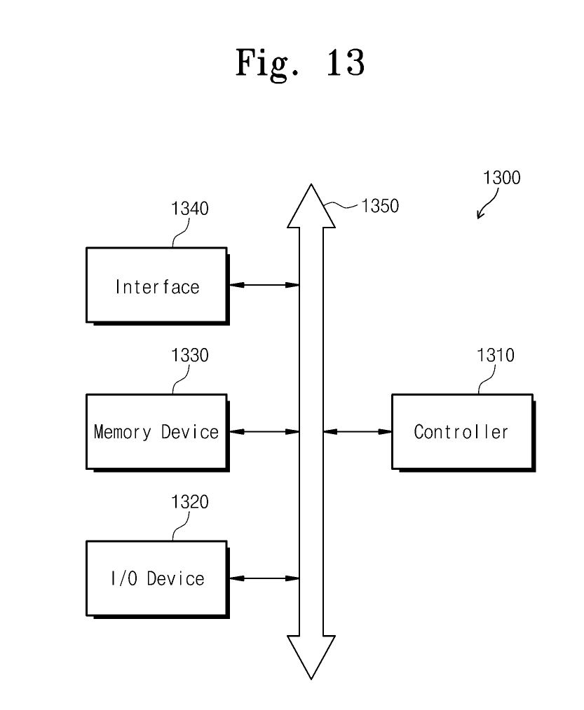

The semiconductor chip packaging methods described above can be applied to realize electronic systems. FIG. 13 is a schematic diagram illustrating an electronic system including a semiconductor chip package according to an exemplary embodiment of the inventive concept.

Referring to FIG. 13, an electronic system 1300 includes a controller 1310, an input/output (I/O) device 1320, and a memory device 1330. The controller 1310, the I/O device 1320, and the memory device 1330 are electronically connected to each other via a bus 1350. The controller 1310 includes, for example, at least one of microprocessors, digital signal processors, microcontrollers, or logic devices. The controller 1310 and the memory device 1330 are packaged in a form of the semiconductor chip packages described with reference to FIGS. 6 through 11. The input-output unit 1320 includes at least one of a keypad, a keyboard, or a display device. The memory device 1330 is configured to store a command code to be used by the controller 1310 and/or user data. In an embodiment; the memory device 1330 includes a volatile memory device or a nonvolatile memory device. In an embodiment, the electronic system 1300 includes a storage including at least one FLASH memory device, which is used to store a large volume of data. The electronic system 1300 further includes an interface 1340 configured to transmit data to or receive data from a communication network. The interface 1340 is configured to process wired data and/or wireless data. For instance, the interface 1340 includes, for example, an antenna, a wireless transceiver, or so on. According to an embodiment, the electronic system 1300 further includes an application chipset, a camera image sensor (CIS), or so forth.

The electronic system 1300 is used in a mobile system, a personal computer, an industrial computer, or an application system configured to process diverse functions. For instance, the electronic system 1300 is used in one of a personal digital assistant (PDA), a laptop computer, a mobile computer, a web tablet, a wireless phone, a memory card, a cell phone, a digital music player, a wire or wireless electronic device, or a complex electronic device including at least two thereof. Or, the electronic system 1300 is used in a communication system, such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, MMDS, or so forth.

According to the exemplary embodiments of the inventive concept, a method of manufacturing a semiconductor chip package includes forming semiconductor chips, each of which has interconnection patterns exposed to the outside, stacking the semiconductor chips such that the interconnection patterns directly contact each other, and then reflowing the interconnection patterns to electrically connect the semiconductor chips with each other. As a result, the stacked semiconductor chips can be electrically connected with each other, without an additional process for such connection, and a size of the semiconductor chip package can be reduced.

While an exemplary embodiment of the inventive concept have been particularly shown and described, it will be understood by one of ordinary skill in the art that variations in form and detail may be made therein without departing from the spirit and scope of the attached claims.

1. A method of manufacturing a semiconductor chip package, comprising:
forming a plurality of semiconductor chips, each of the semiconductor chips comprising,
a semiconductor substrate having a front surface and a back surface,
a chip pad on the front surface of the semiconductor substrate, and
an interconnection pattern extending from the chip pad along a sidewall of the semiconductor substrate;
stacking the semiconductor chips such that the interconnection patterns of the semiconductor chips directly contact each other; and
reflowing the interconnection patterns of the semiconductor chips.

2. The method of claim 1, wherein the interconnection pattern comprises a first connection portion contacting a top surface of the chip pad and a sidewall portion extending from the first connection portion along the sidewall of the semiconductor substrate.

3. The method of claim 2, wherein the interconnection pattern further comprises a second connection portion extending from the sidewall portion outwardly of the semiconductor substrate.

4. The method of claim 3, wherein the first connection portion, the sidewall portion, and the second connection portion have a uniform thickness.

5. The method of claim 3, wherein the stacking of the semiconductor chips is performed such that a first connection portion of a first interconnection pattern overlaps a second connection portion of a second interconnection pattern, wherein the second interconnection pattern is adjacently disposed on the first interconnection pattern.

6. The method of claim 3, wherein the stacking of the semiconductor chips is performed such that a sidewall of a first connection portion of a first interconnection pattern contacts a sidewall of a second connection portion of a second interconnection pattern, wherein the second interconnection pattern is adjacently disposed on the first interconnection pattern.

7. The method of claim 1, wherein the interconnection pattern is formed of a solder material or a metallic material.

8. The method of claim 1, further comprises:
preparing a wafer including chip regions and a scribe line region between the chip regions, wherein each of the chip regions includes the chip pad connected to semiconductor integrated circuits;
forming a trench in the scribe line region of the wafer;
forming the interconnection pattern extending an inner wall of the trench to a top surface of the chip pad; and
separating the chip regions of the wafer from each other.

9. The method of claim 8, further comprises:
forming a mask pattern on the wafer, the mask pattern having an opening on the chip pad and on the trench; and
forming a conductive layer in the opening of the mask pattern.

10. The method of claim 8, wherein the wafer comprises a front surface provided with the chip pad and a back surface, and wherein the method further comprises,
grinding the back surface of the wafer and exposing the interconnection pattern.

11. The method of claim 8, further comprising sawing the wafer along the scribe line region.

12. The method of claim 8, further comprising forming an adhesion pattern on the front surface of the semiconductor substrate and exposing the chip pad.

13. The method of claim 12, wherein forming the adhesion pattern on the back surface of the semiconductor substrate is performed before or after the separating of the chip regions from each other.

14. The method of claim 1, wherein the stacking of the semiconductor chips is performed such that the semiconductor chips are stacked to form a terraced structure.

15. The method of claim 1, wherein the stacking of the semiconductor chips is performed such that even-numbered semiconductor chips of the semiconductor chips arc stacked in an inverted structure, and odd-numbered semiconductor chips of the semiconductor chips are stacked with back surfaces of the odd-numbered semiconductor chips facing downward.

16.-19. (canceled)
